(19) United States
(12) Patent Application Publication
(10) Pub. No.: US 2012/0140148 A1
(43) Pub. Date: Jun. 7, 2012

(54) LIQUID CRYSTAL DISPLAY PANEL, METHOD FOR MANUFACTURING LIQUID CRYSTAL DISPLAY PANEL, AND LIQUID CRYSTAL DISPLAY DEVICE

(76) Inventor: Shinya Kadowaki, Osaka-shi (JP)

(21) Appl. No.: 13/389,689

(22) PCT Filed: Jul. 7, 2010
(86) PCT No.: PCT/JP2010/061559

§ 371 Date: Feb. 9, 2012

(30) Foreign Application Priority Data
Nov. 26, 2009 (JP) 2009-269162

(51) Int. Cl. G02F 1/13357; H05K 13/00; G02F 1/1335

(52) U.S. Cl. 349/64; 349/96; 216/13

(57) ABSTRACT

A wire grid polarizer (WG) has (i) a region where linear conductive wires are regularly repeated at a constant pitch (P) and (ii) a region (A) where linear conductive wires are at a pitch larger than the constant pitch (P). The region (A) where the linear conductive wires are at a pitch larger than the constant pitch (P) and a black matrix (2b) included in a liquid crystal display panel are arranged so as to at least partially overlap each other when viewed from above. Accordingly, it is possible to suppress a reduction in display quality even in a case of employing a large-area wire grid polarizer (WG) which has a region where regularity of a pattern of linear conductive wires having a pitch smaller than a wavelength of light for use in a display is disturbed.

### TECHNICAL FIELD

The present invention relates to a liquid crystal display panel including a wire grid polarizer and a method for producing a liquid crystal display panel, and a liquid crystal display device including the liquid crystal display panel.

### BACKGROUND ART

Liquid crystal display devices, which have rapidly become widespread in place of cathode ray tubes (CRT) in recent years, are widely used in television sets and monitors etc. by utilizing their characteristics such as energy saving, small thickness and light weight.

In the field of such liquid crystal display devices, higher luminance is desired for displaying more beautiful images. Although it is possible to achieve higher luminance by increasing luminance of a backlight included in a liquid crystal display device, this causes an increase in power consumption and thus makes it difficult to achieve energy saving.

Therefore, it is necessary to achieve higher luminance of a liquid crystal display device by increasing use efficiency of light from a backlight. In order to improve use efficiency of light from the backlight, there is a method of improving a polarizer included in the liquid crystal display device.

A generally-known conventional liquid crystal display device is configured such that two absorption polarizers are provided on (i) a surface, of a liquid crystal display panel, from which light from backlight enters and (ii) a surface, of the liquid crystal display panel, from which the light is emitted, respectively.

Each of the absorption polarizers is configured such that a certain polarization plane transmits light but another polarization plane perpendicular to the certain polarization plane absorbs light. In theory, when light from a backlight enters such an absorption polarizer, up to 50% of the light only is to be emitted.

That is, according to the foregoing conventional liquid crystal display device including the two absorption polarizers, approximately 36% to 40% of incident light from the backlight only is to be emitted, substantially. With use of such a configuration, it is difficult to improve use efficiency of light from a backlight and to thereby achieve higher luminance of a liquid crystal display device.

Under such circumstances, there has also been proposed a liquid crystal display device including a reflective polarizer in which a certain polarization plane transmits light and another polarization plane perpendicular to the certain polarization plane reflects light.

The liquid crystal display device including the reflective polarizer is configured such that light reflected by the reflective polarizer, after its polarization plane is randomized by a diffusing layer provided to a backlight, again passes through the reflective polarizer.

Note however that, since the reflective polarizer has an extremely small polarization extinction ratio, it is necessary to employ the foregoing two absorption polarizers in addition to the reflective polarizer, in order to satisfy contrast required for a display.

For this reason, according to the liquid crystal display device including the reflective polarizer, it is not possible to improve use efficiency of light from a backlight to a satisfactory extent although it is possible to improve the use efficiency to some extent.

In view of this, there is proposed a liquid crystal display device including a wire grid polarizing plate, which is obtained by providing linear conductive wires on a glass substrate with a pitch smaller than a wavelength of light from a backlight.

The wire grid polarizing plate is configured to reflect a polarization component parallel to the linear conductive wires and transmit a polarization component perpendicular to the linear conductive wires.

Since it is known that such a wire grid polarizing plate has relatively high transmittance and relatively large polarization extinction ratio, a liquid crystal display device including a wire grid polarizing plate has been attracting attention.

Meanwhile, as a liquid crystal display device has increased in size, the foregoing wire grid polarizing plate has also increased in size. Accordingly, there has been an increase in area that requires a pattern of linear conductive wires having a pitch smaller than a wavelength of light from a backlight, i.e., area that requires a nanometer-sized pattern.

It is difficult to form the foregoing nanometer-sized pattern at a time on a large substrate having a large area. Therefore, generally, the nanometer-sized pattern is formed in batches on the large-area substrate by a step-and-repeat method with use of a mask or a stamp etc. which is capable of forming a pattern in a part of the substrate.

For example, Patent Literature 1 describes a method of producing a large-area wire grid polarizing plate by a step-and-repeat method with use of a stamp.

FIG. 15 illustrates a wire grid polarizing plate formed by a step-and-repeat method with use of a stamp.

A stamp 100 has thereon an elastomer layer having a nanometer-sized pattern. A surface of the elastomer layer, on which surface the pattern is formed, is covered with a resist.

On the other hand, on an entire surface of a substrate 101, a metal layer made of gold, copper or silver etc. is provided.

The surface of the elastomer layer, on which surface the pattern is formed and which is covered with the resist, is brought into contact with the metal layer on the substrate 101, thereby the resist is transferred to the metal layer.

After such a transferring step is carried out with respect to a substantially entire surface of the entire substrate 101, a part of the metal layer which part is not covered with the resist is etched, and the resist is also removed. In this way, it is possible to produce the substrate 101 (large-area wire grid polarizing plate) which has thereon a metal layer formed into a pattern of linear conductive wires having a nanometer-sized small pitch.

Use of such a large-area wire grid polarizing plate makes it possible to improve use efficiency of light from a backlight.

### CITATION LIST

### Patent Literatures

### Patent Literature 1

Japanese Translation of PCT Patent Application, Tokuhyo, No. 2008-522226 A (Publication Date: Jun. 26, 2008)

### Patent Literature 2

Japanese Patent Application Publication, Tokukai, No. 2008-296579 A (Publication Date: Dec. 11, 2008)

### Patent Literature 3

Japanese Patent Application Publication, Tokukai, No. 2006-84776 A (Publication Date: Mar. 30, 2006)

### Patent Literature 4

Japanese Patent Application Publication, Tokukai, No. 2005-203797 A (Publication Date: Jul. 28, 2005)

### Patent Literature 5

U.S. Pat. No. 7,077,992

### SUMMARY OF INVENTION

### Technical Problem

However, when bringing the elastomer layer of the stamp 100 described in Patent Literature 1 into contact with the metal layer of the substrate 101 to thereby carry out a step of transferring the resist to the metal layer multiple times with respect to the substantially entire surface of the substrate 101, it is not possible to control, with high accuracy at a nanometer level, a location where the elastomer layer of the stamp 100 makes contact with the metal layer of the substrate 101.

This causes a problem in which, in a border region (joint) between (i) a first region that corresponds to the size of the stamp 100 and is formed by one (1) transferring step and (ii) a second region that corresponds to the size of the stamp 100, that is adjacent to the first region, and that is formed by the next transferring step, regularity of the pattern of linear conductive wires having a nanometer-sized small pitch is disturbed and thus optical characteristics are dramatically reduced.

FIG. 16 is a view illustrating a large-area wire grid polarizing plate 201 having a region A where regularity of the pattern of linear conductive wires having a nanometer-sized small pitch is disturbed. The wire grid polarizing plate 201 is provided on a surface, of a TFT substrate 202, which is opposite to a surface on which TFT elements are provided.

It should be noted that FIG. 16 illustrates only gate electrode layers 203 included in the TFT elements.

As illustrated in FIG. 16, the wire grid polarizing plate 201 has the region A where regularity of the pattern of linear conductive wires having a nanometer-sized small pitch is disturbed.

The wire grid polarizing plate 201 is configured to reflect a polarization component Ls parallel to the linear conductive wires and transmits a polarization component Lp perpendicular to the linear conductive wires. Note however that, in the region A (where the pitch of the pattern of linear conductive wires is large), the polarization component Ls which is not perpendicular to the linear conductive wires etc. are also transmitted. Accordingly, a liquid crystal display panel and a liquid crystal display device each including the wire grid polarizing plate 201 have dramatically reduced display quality.

FIG. 17 is a view illustrating a large-area wire grid polarizing plate 201 having the foregoing region A where regularity is disturbed. The wire grid polarizing plate 201 is provided on a surface, of a counter substrate 204, which is opposite to a surface on which a black matrix 205 and red, green and blue color filter layers 206R, 206G and 206B are provided.

Also in a case of FIG. 17, in the same manner as in FIG. 16, in the region A (where the pitch of the pattern of linear conductive wires is large), the polarization component Ls which is not perpendicular to the linear conductive wires etc. are also transmitted. Accordingly, a liquid crystal display panel and a liquid crystal display device each including the wire grid polarizing plate 201 have dramatically reduced display quality.

The present invention has been made in view of the problem, and an object of the present invention is to provide a liquid crystal display panel and a method for producing a liquid crystal display panel, and a liquid crystal display device each of which is capable of suppressing a reduction in display quality even in a case of employing a large-area wire grid polarizer having a region where regularity of a pattern of linear conductive wires having a pitch smaller than a wavelength of light for use in a display is disturbed.

### Solution to Problem

In order to attain the above object, a liquid crystal panel in accordance with the present invention is a liquid crystal display panel including: a wire grid polarizer which has a pattern of linear conductive wires having a pitch smaller than a wavelength of light for use in a display; and a light shielding layer, the wire grid polarizer having (i) a first region where the linear conductive wires are regularly repeated at a constant pitch and (ii) a second region where the linear conductive wires are at a pitch larger than the constant pitch, and the second region and the light shielding layer being arranged so as to at least partially overlap each other when viewed from above.

Generally, due to limit of accuracy in its production technique, a large-area wire grid polarizer has (i) a region where linear conductive wires are regularly repeated at a constant pitch smaller than a wavelength of light for use in a display and (ii) a region where linear conductive wires are at a pitch larger than the constant pitch.

Such a wire grid polarizer is configured such that, in the region where the linear conductive wires are regularly repeated at the constant pitch, (i) a polarization component parallel to the linear conductive wires is reflected and (ii) a polarization component perpendicular to the linear conductive wires is transmitted.

However, in the region where the linear conductive wires are at a pitch larger than the constant pitch, a polarization component which is not perpendicular to the linear conductive wires etc. are also transmitted. Accordingly, a liquid crystal display panel including such wire grid polarizer has dramatically reduced display quality.

According to the above configuration, the wire grid polarizer is configured such that (i) the region where the linear conductive wires are at a pitch larger than the constant pitch and (ii) the light shielding layer included in the liquid crystal display panel at least partially overlap each other when viewed from above.

Accordingly, in the liquid crystal display panel, it is possible for the light shielding layer to block light, which is to transmit the region where the linear conductive wires are at a pitch larger than the constant pitch and thus causes a reduction in display quality. This makes it possible to achieve a liquid crystal display panel which is capable of suppressing a reduction in display quality even in a case of employing a large-area wire grid polarizer which has a region where regularity of a pattern of linear conductive wires having a pitch smaller than a wavelength of light for use in a display is disturbed.

It should be noted that the pitch is a sum of (i) a width of a linear conductive wire in a direction perpendicular to a direction of extension of the linear conductive wire and (ii) a width of a gap between linear conductive wires in a direction perpendicular to a direction of extension of the linear conductive wires.

In order to attain the above object, a liquid crystal display device in accordance with the present invention is a liquid crystal display device including: the foregoing liquid crystal display panel; and a surface light source device for irradiating the liquid crystal display panel with light, the surface light source device (i) having an irregularly-shaped light emitting surface for scattering light and/or (ii) having on its light emitting surface a diffusing member for scattering light.

The configuration includes the liquid crystal display panel. This makes it possible to achieve a liquid crystal display device which is capable of suppressing a reduction in display quality even in a case of employing a large-area wire grid polarizer which has a region where regularity of a pattern of linear conductive wires having a pitch smaller than a wavelength of light for use in a display is disturbed.

Further, according to the configuration, the surface light source device (i) has the irregularly-shaped light emitting surface for scattering light and/or (ii) has, on its light emitting surface, the diffusing member for scattering light. This causes a polarization component reflected by the wire grid polarizer to be diffused by the irregularly-shaped light emitting surface and/or the diffusing member, and thus makes it possible to reuse the polarization component. As such, it is possible to achieve a liquid crystal display device having high use efficiency of light.

In order to attain the above object, a method for producing a liquid crystal display panel in accordance with the present invention is a method for producing a liquid crystal display panel, the liquid crystal display panel including (i) a wire grid polarizer which has a pattern of linear conductive wires having a pitch smaller than a wavelength of light for use in a display and (ii) substrates, said method including the steps of: (A) forming, on one of the substrates, a light shielding layer patterned into a predetermined shape; (B) forming, evenly on an entire surface of said one of the substrates, a conductive film which is to be formed into the conductive wires; (C) forming a resist so that the resist covers the conductive film; (D) curing a part of the resist while pressing a patterned surface of a first mold against the part of the resist, the patterned surface being a surface in which linear patterns regularly repeated at a constant pitch smaller than the wavelength of the light are formed, to thereby form in the resist a first transferred surface on which the linear patterns in the patterned surface have been transferred; (E) after relocating the first mold to a position adjacent to the first transferred surface, curing another part of the resist while pressing the patterned surface of the first mold against said another part of the resist to thereby form in the resist a second transferred surface on which the linear patterns in the patterned surface have been transferred; in steps (D) and (E), locating the first mold such that a border between the first transferred surface and the second transferred surface at least partially overlaps the light shielding layer when viewed from above; (F) etching the conductive film by using cured resist patterns as masks; and (G) removing the cured resist patterns.

Also in a case of being produced by a step-and-repeat method with use of the first mold (small mold) having the patterned surface where the linear patterns regularly repeated at the constant pitch smaller than the wavelength of the light are formed, due to limit of accuracy in its production technique, a large-area wire grid polarizer has (i) a region where linear conductive wires are regularly repeated at a constant pitch smaller than a wavelength of light for use in a display and (ii) a region where linear conductive wires are at a pitch larger than the constant pitch (this region corresponds to a border between the first and second transferred surfaces adjacent to each other).

According to the configuration, the first mold is located such that the border between the first and second transferred surfaces adjacent to each other at least partially overlaps the light shielding layer when viewed from above. Accordingly, in the liquid crystal display panel, it is possible for the light shielding layer to block light, which is to transmit the border between the first and second transferred surfaces adjacent to each other and thus causes a reduction in display quality. This makes it possible to achieve a method for producing a liquid crystal display panel which method is capable of suppressing a reduction in display quality even in a case of employing a large-area wire gird polarizer produced with use of the first mold (small mold).

In order to attain the above object, a method for producing a liquid crystal display panel in accordance with the present invention is a method for producing a liquid crystal display panel, the liquid crystal display panel including (i) a wire grid polarizer which has a pattern of linear conductive wires having a pitch smaller than a wavelength of light for use in a display and (ii) substrates, said method including the steps of: (A) forming, on one of the substrates, a light shielding layer patterned into a predetermined shape; (B) forming, evenly on an entire surface of said one of the substrates, a conductive film which is to be formed into the conductive wires; (C) forming a resist so that the resist covers the conductive film; (D) curing the resist while pressing a patterned surface of a second mold against the resist, the patterned surface of the second mold having (i) a first region in which linear patterns regularly repeated at a constant pitch smaller than the wavelength of the light are formed and (ii) a second region in which linear patterns are at a pitch larger than the constant pitch; in step (D), locating the second mold such that the second region at least partially overlaps the light shielding layer when viewed from above; (E) etching the conductive film by using cured resist patterns as masks; and (F) removing the cured resist patterns.

Due to limit of accuracy in its production technique, the second mold (large mold) for use in production of a large-wire grid polarizer has (i) a region where linear patterns regularly repeated at the constant pitch smaller than the wavelength of the light are formed and (ii) a region where linear patterns are at a pitch larger than the constant pitch.

According to the configuration, the second mold is located such that the region of the patterned surface of the second mold, in which region the linear patterns are at a pitch larger than the constant pitch, at least partially overlaps the light shielding layer when viewed from above. Accordingly, in the liquid crystal display panel, it is possible for the light shielding layer to block light, which is to transmit the region where the linear conductive wires are at a pitch larger than the constant pitch and thus causes a reduction in display quality. This makes it possible to achieve a method for producing a liquid crystal display panel which method is capable of suppressing a reduction in display quality even in a case of employing a large-area wire grid polarizer produced with use of the second mold (large mold).

### Advantageous Effects of Invention

As has been described, a liquid crystal display panel in accordance with the present invention is configured such that the wire grid polarizer has (i) a first region where the linear conductive wires are regularly repeated at a constant pitch and (ii) a second region where the linear conductive wires are at a pitch larger than the constant pitch, and the second region and the light shielding layer are arranged so as to at least partially overlap each other when viewed from above.

Further, as has been described, a liquid crystal display device in accordance with the present invention includes: the foregoing liquid crystal display panel; and a surface light source device for irradiating the liquid crystal display panel with light, the surface light source device (i) having an irregularly-shaped light emitting surface for scattering light and/or (ii) having on its light emitting surface a diffusing member for scattering light.

Further, as has been described, a method for producing a liquid crystal display panel in accordance with the present invention includes the steps of: (A) forming, on one of the substrates, light shielding layer patterned into a predetermined shape; (B) forming, evenly on an entire surface of said one of the substrates, a conductive film which is to be formed into the conductive wires; (C) forming a resist so that the resist covers the conductive film; (D) curing a part of the resist while pressing a patterned surface of a first mold against the part of the resist, the patterned surface being a surface in which linear patterns regularly repeated at a constant pitch smaller than the wavelength of the light are formed, to thereby form in the resist a first transferred surface on which the linear patterns in the patterned surface have been transferred; (E) after relocating the first mold to a position adjacent to the first transferred surface, curing another part of the resist while pressing the patterned surface of the first mold against said another part of the resist to thereby form in the resist a second transferred surface on which the linear patterns in the patterned surface have been transferred; in steps (D) and (E), locating the first mold such that a border between the first transferred surface and the second transferred surface at least partially overlaps the light shielding layer when viewed from above; (F) etching the conductive film by using cured resist patterns as masks; and (G) removing the cured resist patterns.

Alternatively, as has been described, a method for producing a liquid crystal display panel in accordance with the present invention includes the steps of: (A) forming, on one of the substrates, a light shielding layer patterned into a predetermined shape; (B) forming, evenly on an entire surface of said one of the substrates, a conductive film which is to be formed into the conductive wires; (C) forming a resist so that the resist covers the conductive film; (D) curing the resist while pressing a patterned surface of a second mold against the resist, the patterned surface of the second mold having (i) a first region in which linear patterns regularly repeated at a constant pitch smaller than the wavelength of the light are formed and (ii) a second region in which linear patterns are at a pitch larger than the constant pitch; in step (D), locating the second mold such that the second region at least partially overlaps the light shielding layer when viewed from above; (E) etching the conductive film by using cured resist patterns as masks; and (F) removing the cured resist patterns.

Accordingly, it is possible to achieve a liquid crystal display panel and a method for producing a liquid crystal display panel, and a liquid crystal display device each of which is capable of suppressing a reduction in display quality even in a case of employing a large-area wire grid polarizer which has a region where regularity of a pattern of linear conductive wires having a pitch smaller than a wavelength of light for use in a display is disturbed.

### BRIEF DESCRIPTION OF DRAWINGS

FIG. 1 is a view schematically illustrating a configuration of a counter substrate of a liquid crystal display panel included in a liquid crystal display device of an embodiment of the present invention.

FIG. 2 is a view schematically illustrating a configuration of the liquid crystal display device of the embodiment of the present invention.

FIG. 3 is a view illustrating a modification of the liquid crystal display device of the embodiment of the present invention.

FIG. 4 is a view schematically illustrating a process of producing a small mold.

FIG. 5 is a view schematically illustrating a process of producing a large mold.

FIG. 6 is a view schematically illustrating a process of producing a wire grid polarizer included in the liquid crystal display device shown in FIG. 3 with use of the small mold shown in FIG. 4.

FIG. 7 is a view schematically illustrating a process of producing a wire grid polarizer included in the liquid crystal display device shown in FIG. 3 with use of a large mold.

FIG. 8 is a view schematically illustrating a process of producing an in-cell wire grid polarizer included in the liquid crystal display device shown in FIG. 2 with use of a large mold.

FIG. 9 is a view illustrating part of a process of producing an in-cell wire grid polarizer included in the liquid crystal display device shown in FIG. 2 with use of a small mold.

FIG. 10 is a view illustrating a counter substrate on which an in-cell wire grid polarizer is provided, which counter substrate is included in a liquid crystal display device of another embodiment of the present invention.

FIG. 11 is a view for describing a liquid crystal display device of a further embodiment of the present invention, which liquid crystal display device employs as a light source an LED that emits blue light. (a) of FIG. 11 schematically illustrates a configuration of the liquid crystal display device. (b) of FIG. 11 illustrates a counter substrate on which an in-cell wire grid polarizer is provided, which counter substrate is included in the liquid crystal display device.

FIG. 12 is a view for describing a liquid crystal display device of still a further embodiment of the present invention, which liquid crystal display device employs as a light source an LED that emits blue light. (a) of FIG. 12 schematically illustrates a configuration of the liquid crystal display device. (b) of FIG. 12 illustrates a counter substrate on which an in-cell wire grid polarizer is provided, which counter substrate is included in the liquid crystal display device.

FIG. 13 is a view for describing a liquid crystal display device of still a further embodiment of the present invention, which liquid crystal display device employs as a light source an LED that emits ultraviolet light. (a) of FIG. 13 schematically illustrates a configuration of the liquid crystal display device. (b) of FIG. 13 illustrates a counter substrate on which an in-cell wire grid polarizer is provided, which counter substrate is included in the liquid crystal display device.

FIG. 14 is a view for describing a liquid crystal display device of still a further embodiment of the present invention, which liquid crystal display device employs as a light source an LED that emits ultraviolet light. (a) of FIG. 14 schematically illustrates a configuration of the liquid crystal display device. (b) of FIG. 14 illustrates a counter substrate on which an in-cell wire grid polarizer is provided, which counter substrate is included in the liquid crystal display device.

FIG. 15 is a view illustrating a conventional wire grid polarizing plate, which is formed by a step-and-repeat method with use of a stamp.

FIG. 16 is a view illustrating how a large-area wire grid polarizing plate, which has a region where regularity of a pattern of linear conductive wires having a nanometer-sized small pitch is disturbed, is provided on a surface of a TFT substrate which surface is opposite to a surface on which TFT elements are provided.

FIG. 17 is a view illustrating how a large-area wire grid polarizing plate, which has a region where regularity is disturbed, is provided on a surface of a counter substrate which surface is opposite to a surface on which a black matrix and red, green and blue color filter layers are provided.

### DESCRIPTION OF EMBODIMENTS

The following description discusses, with reference to the drawings, embodiments of the present invention in detail. Note, however, that dimensions, materials, shapes, and relative positions of constituents described in the embodiments are mere examples, and therefore the scope of the claims should not be limited to those described in the embodiments.

### Embodiment 1

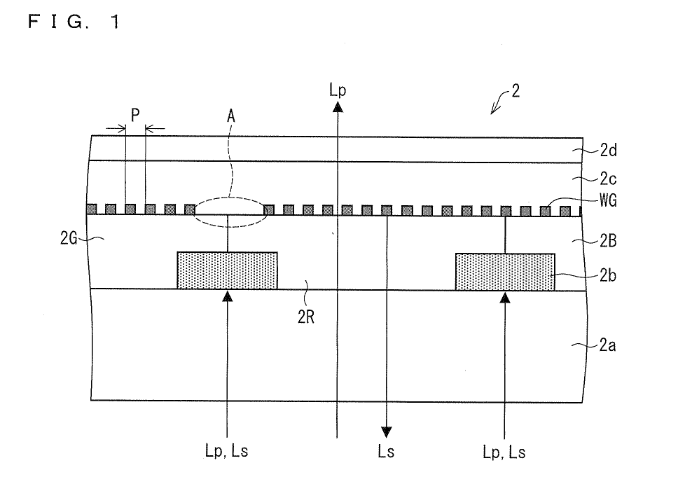

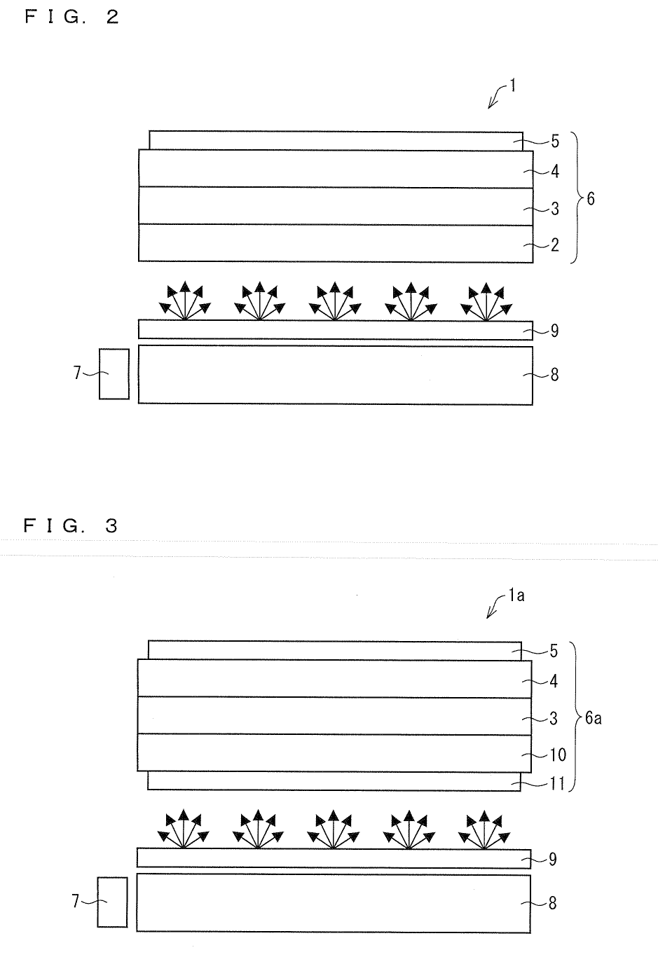

The following description discusses, with reference to FIGS. 1 and 2, a configuration of a liquid crystal display device including a wire grid polarizer.

FIG. 2 is a view schematically illustrating a configuration of a liquid crystal display device 1 of the present embodiment.

As illustrated in FIG. 2, the liquid crystal display device 1 includes: a liquid crystal display panel 6; a surface light source device which includes a light source 7 for irradiating the liquid crystal display panel 6 with light and a light guide plate 8 for emitting the light from the light source 7 in the form of plane emission; and an optical sheet including a diffusing plate 9 which is for further uniformizing the light emitted from the surface light source device and is provided on a light-emitting surface of the surface light source device.

The liquid crystal display panel 6 includes a counter substrate 2 and a TFT array substrate 4. These substrates 2 and 4 are bonded together with use of a sealing material (not illustrated), and a liquid crystal layer 3 is sealed between these substrates 2 and 4.

As illustrated in FIG. 2, according to the present embodiment, an absorption polarizing plate 5 is provided on a surface, of the TFT array substrate 4, which is opposite to a surface in contact with the liquid crystal layer 3. That is, the absorption polarizing plate 5 is provided on a display surface of the liquid crystal display panel 6. The counter substrate 2 has a wire grid polarizer (not illustrated, described later) on its surface in contact with the liquid crystal layer 3.

FIG. 1 is a view schematically illustrating a configuration of the counter substrate 2 of the liquid crystal display panel 6 included in the liquid crystal display device 1 of the present embodiment shown in FIG. 2.

As illustrated in FIG. 1, black matrices 2b (light shielding layer) having light blocking property are provided on a glass substrate 2a. The black matrices 2b are made from a thin metal film of for example chromium or from photosensitive resin containing carbon black.

It should be noted that, according to the present embodiment, the black matrices 2b are configured such that the width of each of them is approximately 5 μm to 20 μm and the width of an aperture between them is approximately 20 μm to 300 μm. Note, however, that this does not imply any limitation.

Further, a red colored layer (color filter layer) 2R, a green colored layer (color filter layer) 2G and a blue colored layer (color filter layer) 2B, which layers serve as a color control layer, are provided such that a border between colors lies on a black matrix 2b.

It should be noted that, although the foregoing three types of colored layers 2R, 2G and 2B are provided according to the present embodiment, the color and the number etc. thereof are not limited to the above.

Further, according to the present embodiment, the colored layers 2R, 2G and 2B are made with use of photosensitive resists of three colors containing dispersion liquids of pigments of these colors. However, this does not imply any limitation.

Further, according to the present embodiment, a colored layer (color filter layer) is used as the color control layer. However, the color control layer is not limited to this provided that the color control layer is capable of emitting incident light as light of a plurality of different colors.

Furthermore, according to the present embodiment, an overcoating (not illustrated) made of thermosetting transparent resin or photo-curing transparent resin is provided as a planarizing layer on the colored layers 2R, 2G and 2B. However, the overcoating can be omitted if the colored layers 2R, 2G and 2B are provided evenly without bumps.

On the overcoating, a wire grid polarizer WG is provided. The wire grid polarizer WG has a pattern of linear conductive wires having a pitch P smaller than a wavelength of light for use in a display, which light is emitted from the surface light source device.

Further, on the wire grid polarizer WG, a protective film 2c is provided. On the protective film 2c, a transparent electrode 2d made of ITO (Indium Tin Oxide) or IZO (Indium Zinc Oxide) etc. is provided.

It should be noted that the pitch P is a sum of (i) a width of a linear conductive wire in a direction perpendicular to a direction of extension of the linear conductive wire and) a width of a gap between linear conductive wires in a direction perpendicular to a direction of extension of the linear conductive wires.

As illustrated in FIG. 1, generally, due to limit of accuracy in its production technique, a large-area wire grid polarizer WG has (i) a region where linear conductive wires are regularly repeated at a constant pitch P smaller than a wavelength of light for use in a display and (ii) a region A where linear conductive wires are at a pitch larger than the constant pitch.

Such a wire grid polarizer WG is configured such that, in the region where the linear conductive wires are regularly repeated at the constant pitch, (i) a polarization component Ls parallel to the linear conductive wires is reflected and (ii) a polarization component Lp perpendicular to the linear conductive wires is transmitted.

However, in the region A where the linear conductive wires are at a pitch larger than the constant pitch P, a polarization component which is not perpendicular to the linear conductive wires, e.g., the polarization component Ls parallel to the linear conductive wires etc., is also transmitted. Accordingly, a liquid crystal display panel including such a wire grid polarizer WG has dramatically reduced display quality.

As illustrated in FIG. 1, in the counter substrate 2 of the liquid crystal display panel 6 included in the liquid crystal display device 1 of the present embodiment, the region A of the wire grid polarizer WG in which region the linear conductive wires are at a pitch larger than the constant pitch P and a black matrix 2b provided on the counter substrate 2 are arranged so as to completely overlap each other when viewed from above. Note, however, that the region A and the black matrix 2b can be arranged so as to partially overlap each other when viewed from above. This still makes it possible to bring about an effect.

According to this configuration, in the liquid crystal display panel 6, it is possible for the black matrix 2b to block light, which is to transmit the region A where the linear conductive wires are at a pitch larger than the constant pitch P and thus causes a reduction in display quality. This makes it possible to achieve a liquid crystal display device 6 which is capable of suppressing a reduction in display quality even in a case of employing a large-area wire grid polarizer WG which has a region A where regularity of a pattern of linear conductive wires having a pitch P smaller than a wavelength of light for use in a display is disturbed.

According to the present embodiment, the black matrix 2b is used as a light shielding layer. Note, however, that the light shielding layer is not limited to this. Alternatively, a metal wire (not illustrated) connected to a TFT element provided on the TFT array substrate 4 can be used as a light shielding layer. Further, a light shielding layer can be separately provided in addition to the black matrix 2b and/or the metal wire.

Further, for example both the black matrix 2b and the metal wire can be used as light shielding layers. Specifically, for example in a case of a COA (Color Filter On Array) structure in which black matrices and metal wires are provided on a TFT array substrate, it is possible to configure this structure such that (i) part of the region A of the wire grid polarizer WG in which region the linear conductive wires are at a pitch larger than the constant pitch P partially overlaps a black matrix when viewed from above and (ii) another part of the region A partially overlaps a metal wire when viewed from above.

It should be noted that, according to the present embodiment, for the purpose of reducing thickness of the liquid crystal display panel 6 and improving durability of the wire grid polarizer WG, the wire grid polarizer WG is provided between the glass substrate 2a of the counter substrate 2 and the TFT array substrate 4. That is, the wire grid polarizer WG is provided in an in-cell manner. However, this does not imply any limitation.

FIG. 3 is a view illustrating a modification of the liquid crystal display device of the present embodiment.

As illustrated in FIG. 3, a liquid crystal display panel 6a included in a liquid crystal display device 1a is different from the liquid crystal display panel 6 included in the liquid crystal display device 1 shown in FIG. 2 in that the wire grid polarizer WG is provided not to a counter substrate 10 but to another substrate 11.

According also to such a configuration, it is possible to achieve a liquid crystal display panel 6a capable of suppressing a reduction in display quality, by arranging (i) a region A of the wire grid polarizer WG provided to the substrate 11 in which region linear conductive wires are at a pitch larger than the constant pitch P and (ii) a black matrix provided on the counter substrate 10 such that the region A and the black matrix at least partially overlap each other when viewed from above.

Each of the liquid crystal display devices 1 and 1a shown in respective FIGS. 2 and 3 includes: the liquid crystal display panel 6 or 6a; the surface light source device including the light source 7 for irradiating the liquid crystal display panel 6 or 6a with light and the light guide plate 8 for emitting the light from the light source 7 in the form of plane emission; and the optical sheet including the diffusing plate 9 which is for further uniformizing the light emitted from the surface light source device and is provided on the light-emitting surface of the surface light source device.

According to the configuration, the surface light source device has on its light-emitting surface the optical sheet including the diffusing plate 9. This causes the polarization component Ls reflected by the wire grid polarizer WG to be diffused by the optical sheet including the diffusing plate 9, and thus makes it possible to reuse the polarization component Ls. As such, it is possible to achieve a liquid crystal display device 1 or 1a having high use efficiency of light.

(Process of Producing Small Mold)

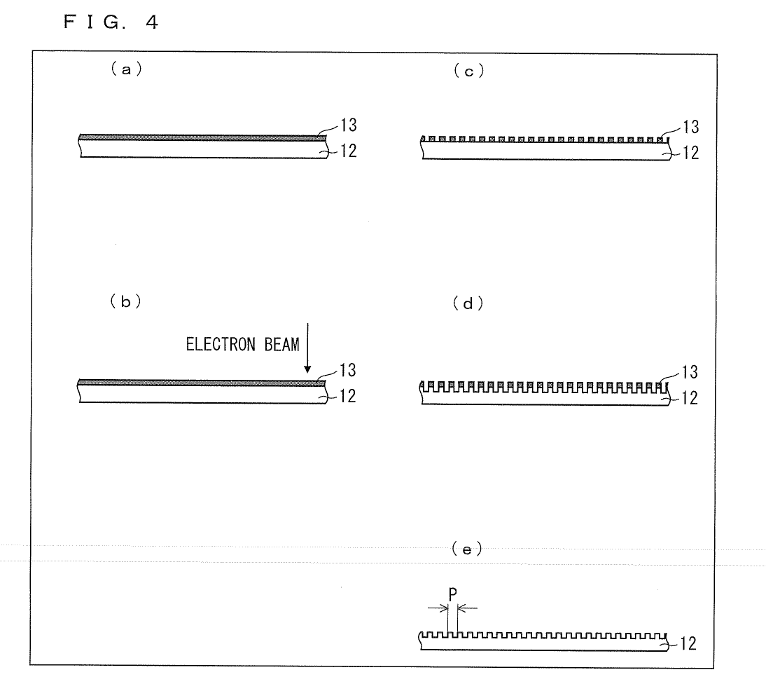

The following description discusses, with reference to FIG. 4, a method of producing a small mold (first mold) capable of being used for production of a large-area wire grid polarizer WG and a large mold (second mold).

FIG. 4 is a view schematically illustrating a process of producing a small mold 12.

First, as illustrated in (a) of FIG. 4, a photosensitive resist 13 is applied to an entire surface of a substrate 12. According to the present embodiment, the substrate 12 is made of quartz. Note, however, that the substrate 12 is not limited to this, and therefore Si wafer etc. can be used. Further, although the photosensitive resist 13 used is a negative photosensitive resist that is cured by exposure to light, it is also possible to use a positive photosensitive resist that is developed by exposure to light.

It should be noted that, in order to prevent time taken for lithography with an electron beam from increasing and to prevent production costs from increasing, it is preferable that the substrate 12 be approximately several millimeters to several centimeters on a side.

Next, as illustrated in (b) of FIG. 4, the photosensitive resist 13 is exposed to light (lithographed with an electron beam) so that linear patterns are formed in the photosensitive resist 13.

Next, as illustrated in (c) of FIG. 4, the photosensitive resist 13 is developed, thereby linear patterns of the photosensitive resist 13 are formed on the substrate 12. The linear patterns have a pitch smaller than a wavelength of light emitted from the surface light source device.

According to the present embodiment, the pitch of the linear patterns is 100 nm. Note, however, that the pitch is not limited to the above, and therefore can be any pitch provided that the pitch is smaller than a wavelength of light emitted from the surface light source device. It is preferable that the pitch be 100 nm to 200 nm.

After that, as illustrated in (d) of FIG. 4, dry etching is carried out by using as masks linear patterns of the photosensitive resist 13, thereby linear patterns having a pitch P smaller than a wavelength of light emitted from the surface light source device are formed in a surface, of the substrate 12, on which the photosensitive resist 13 is provided.

Lastly, as illustrated in (e) of FIG. 4, the linear patterns of the photosensitive resist 13 used as the masks in the foregoing dry etching step are removed. In this way, it is possible to produce the small mold 12 which is made of quartz and all over which the linear patterns having the pitch P smaller than a wavelength of light emitted from the surface light source device are formed.

(Process of Producing Large Mold)

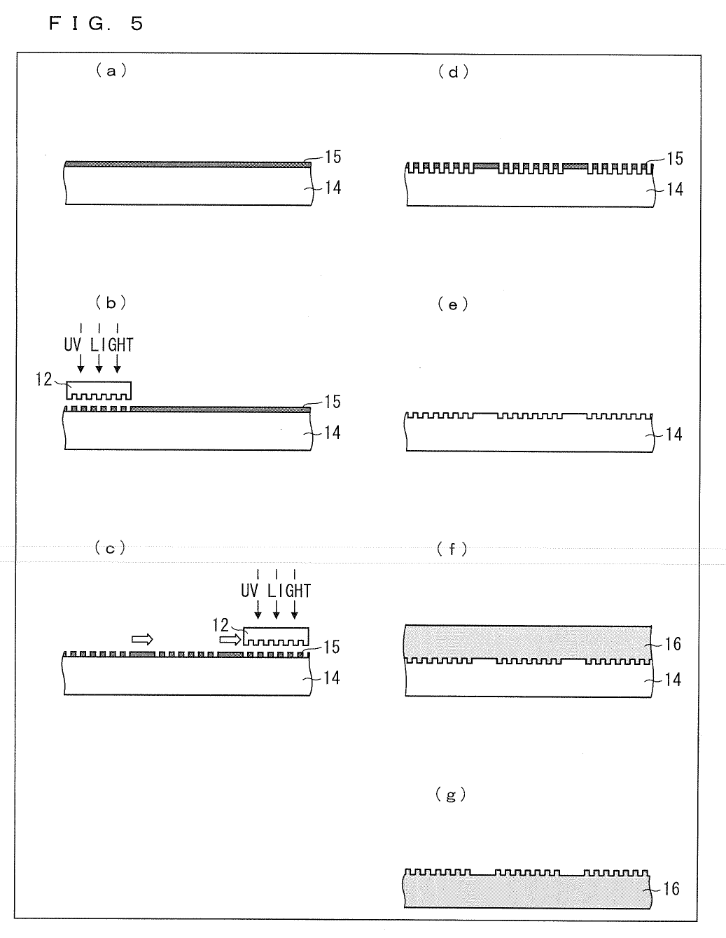

The following description discusses, with reference to FIG. 5, a method of producing a large mold (second mold) which is capable of being used for producing a large-area wire grid polarizer WG.

FIG. 5 is a view schematically illustrating a process of producing large molds 14 and 16.

First, as illustrated in (a) of FIG. 5, a resist 15 is applied to an entire surface of a substrate 14. According to the present embodiment, the substrate 14 is made of quartz. Note, however, that the substrate 14 is not limited to this, and therefore Si wafer etc. can be used. Further, the resist 15 used can either be a photo-curing resist or a thermosetting resist. According to the present embodiment, the resist 15 used is a negative photo-curing resist.

It should be noted that the size of the substrate 14 can be determined according to the size of a screen of a liquid crystal display device. According to the present embodiment, the substrate 14 is several centimeters or greater on a side.

Next, as illustrated in (b) of FIG. 5, a surface of the small mold 12 which is made of quartz and produced in the step of FIG. 4, in which surface the linear patterns are formed (such a surface is hereinafter referred to as a patterned surface), is pressed against a part of the resist 15 provided on the substrate 14. Then, the part of the resist 15 is exposed to UV light through the small mold 12 made of quartz. In this way, patterns of the resist 15, which patterns are complementary to the patterns formed in the patterned surface of the small mold 12, are formed on the substrate 14 (i.e., a surface corresponding to the patterned surface of the small mold 12 is formed, that is, the patterns in the patterned surface of the small mold 12 are transferred onto this surface. Such a surface is hereinafter referred to as a transferred surface). That is, the patterns of the resist 15 are formed on the substrate 14 by a UV imprinting process.

Next, as illustrated in (c) of FIG. 5, the small mold 12 is relocated and the step shown in (b) of FIG. 5 is repeated. In this way, it is possible to form, in the entire surface of the resist 15 provided on the substrate 14, patterns of the resist 15 which patterns are complementary to the patterns formed in the patterned surface of the small mold 12 (i.e., the transferred surface corresponding to the patterned surface of the small mold 12 is formed). That is, it is possible to from patterns in the entire surface of the resist 15 provided on the substrate 14, by a step-and-repeat method.

It should be noted that, according to the present embodiment, the small mold 12 made of quartz is used because UV irradiation is carried out through the small mold 12. Note however that, in a case where the resist 15 is a thermosetting resist, it is possible to use a small mold made of a material having no UV light-transmitting property (having no light-transmitting property). Further, in a case where the resist 15 is a thermosetting resist, instead of UV light irradiation, heat treatment can be carried out in the steps shown in (b) and (c) of FIG. 5 locally with respect to a part of the resist 15 on the substrate 14 against which part the small mold 12 is pressed.

After that, as illustrated in (d) of FIG. 5, dry etching is carried out by using as masks the linear patterns of the resist 15. In this way, linear patterns having a pitch smaller than a wavelength of light emitted from the surface light source device are formed in the surface of the substrate 14 on which surface the resist 15 is provided.

Then, as illustrated in (e) of FIG. 5, the linear patterns of resist 15 used as the masks in the foregoing dry etching step are removed. In this way, it is possible to produce a large mold 14 which is made of quartz and all over which the linear patterns having a pitch smaller than a wavelength of light emitted from the surface light source device are formed.

Further, as illustrated in (f) of FIG. 5, the large mold 14 is immersed in for example a solution containing metal such as nickel, and the solution is electrolyzed so that the nickel etc. are precipitated as a metal layer about 0.3 mm in thickens on a surface of the large mold 14. In this way, a metal layer 16 made of nickel etc. is formed on the large mold 14 by electrotyping.

After that, as illustrated in (g) of FIG. 5, the metal layer 16 is released from the large mold 14. In this way, it is possible to produce another large mold 16 made of metal containing nickel.

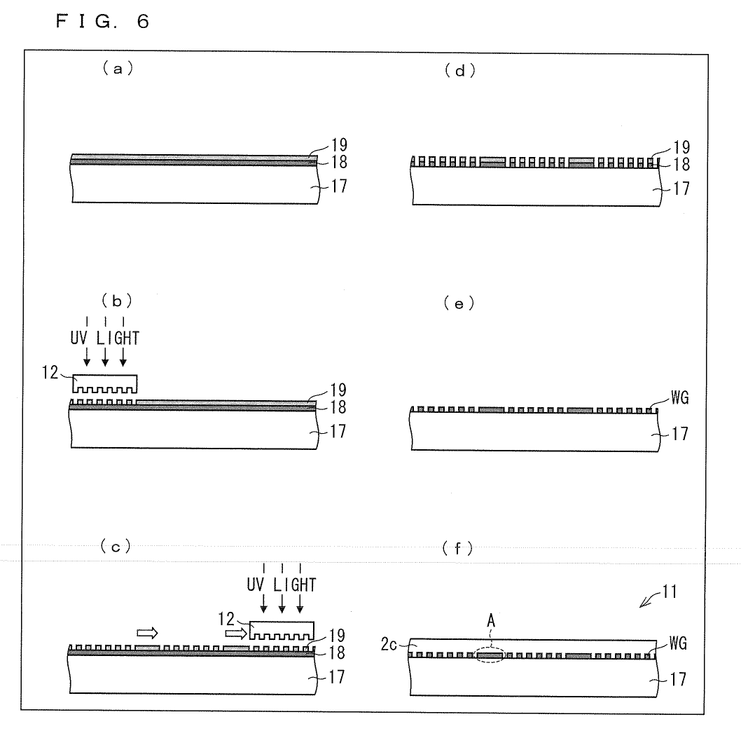

FIG. 6 is a view schematically illustrating a process of producing a wire grid polarizer WG included in the liquid crystal display device 1a shown in FIG. 3 with use of the small mold 12.

First, as illustrated in (a) of FIG. 6, a metal film (conductive film) 18, which will be formed into a pattern of conductive wires, is formed on the entire surface of a substrate 17. Then, a resist 19 is applied so as to cover the metal film 18.

Although the substrate 17 used is a glass substrate according to the present embodiment, the substrate 17 is not limited to this. Further, although the metal film 18 used is made of aluminum according to the present embodiment, the metal film 18 is not limited to this, and therefore can be made of silver or the like.

Further, the resist 19 used can either be a photo-curing resist or a thermosetting resist. According to the present embodiment, the resist 19 used is a negative photo-curing resist.

Next, as illustrated in (b) of FIG. 6, a patterned surface of the small mold 12 which is made of quartz and produced in the step shown in FIG. 4 is pressed against a part of the resist 19 provided on the metal film 18 on the substrate 17. Then, the part of the resist 19 is exposed to UV light through the small mold 12 made of quartz. In this way, patterns of the resist 19, which patterns are complementary to the patterns formed in the patterned surface of the small mold 12, are formed (i.e., a transferred surface corresponding to the patterned surface of the small mold 12 is formed). That is, the patterns of the resist 19 are formed by a UV imprinting process.

Next, as illustrated in (c) of FIG. 6, the small mold 12 is relocated and the step shown in (b) of FIG. 6 is repeated. This makes it possible to from, in the entire surface of the resist 19 provided on the substrate 17, patterns of the resist 19 which patterns are complementary to the patterns formed in the patterned surface of the small mold 12 (i.e., the transferred surface corresponding to the patterned surface of the small mold 12 is formed). That is, it is possible to form patterns in the entire surface of the resist 19 provided on the substrate 17, by a step-and-repeat method.

It should be noted that, according to the present embodiment, the small mold 12 made of quartz is used because UV irradiation is carried out through the small mold 12. Note however that, in a case where the resist 19 is a thermosetting resist, it is possible to use a small mold made of a material having no UV light-transmitting property (having no light-transmitting property). Further, in a case where the resist 19 is a thermosetting resist, instead of UV light irradiation, heat treatment can be carried out in the steps shown in (b) and (c) of FIG. 6 locally with respect to a part of the resist 19 on the substrate 17 against which part the small mold 12 is pressed.

After that, as illustrated in (d) of FIG. 6, etching is carried out by using as masks linear patterns of the resist 19. In this way, linear patterns having a pitch smaller than a wavelength of light emitted from the surface light source device are formed in the metal film 18.

Then, as illustrated in (e) of FIG. 6, the linear patterns of the resist 19 used as the masks in the foregoing etching step are removed. In this way, it is possible to form a wire grid polarizer WG on the substrate 17.

Lastly, as illustrated in (f) of FIG. 6, on the wire grid polarizer WG produced in the step shown in (e) of FIG. 6, a protective film 2c is formed. In this way, it is possible to produce a substrate 11 including the wire grid polarizer WG, which substrate is included in the liquid crystal display device 1a shown in FIG. 3.

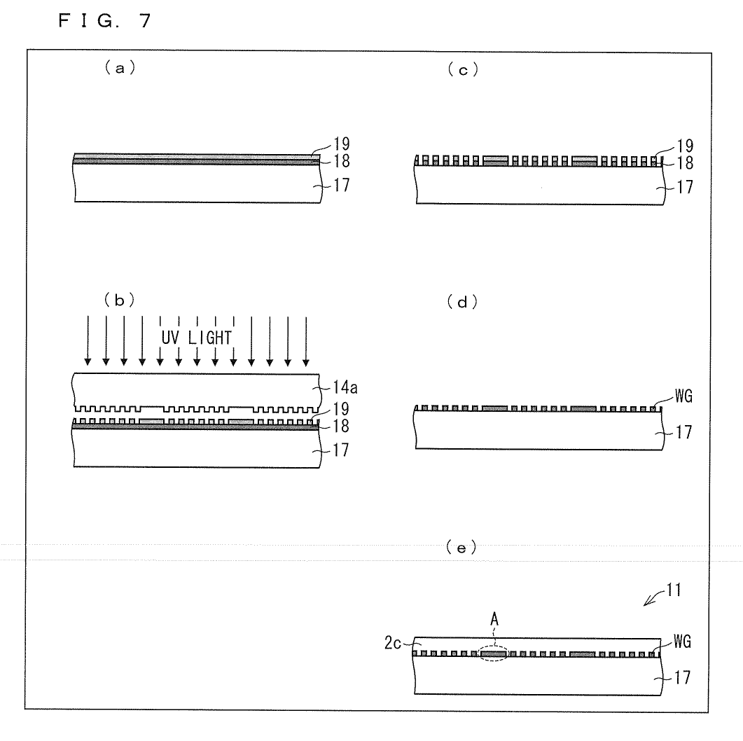

FIG. 7 is a view schematically illustrating a process of producing a wire grid polarizer WG included in the liquid crystal display device 1a shown in FIG. 3 with use of a large mold 14a.

The steps shown in (a) and (c) to (e) of FIG. 7 are the same as those shown in (a) and (d) to (f) of FIG. 6. Therefore, descriptions therefor are omitted here.

It should be noted that, in the step shown in (b) of FIG. 7, the large mold 14a is used. The patterned surface of the large mold 14a is different in shape from that of the large mold 14 produced in the step shown in FIG. 5.

The patterned surface of the large mold 14a is pressed against the resist 19 provided on the metal film 18 on the substrate 17. Then, the resist 19 is exposed to UV light through the large mold 14a made of quartz. In this way, patterns of the resist 19, which patterns are complementary to the patterns formed in the patterned surface of the large mold 14a, are formed (i.e., a transferred surface corresponding to the patterned surface of the large mold 14a is formed). That is, the patterns of the resist 19 are formed by a UV imprinting process.

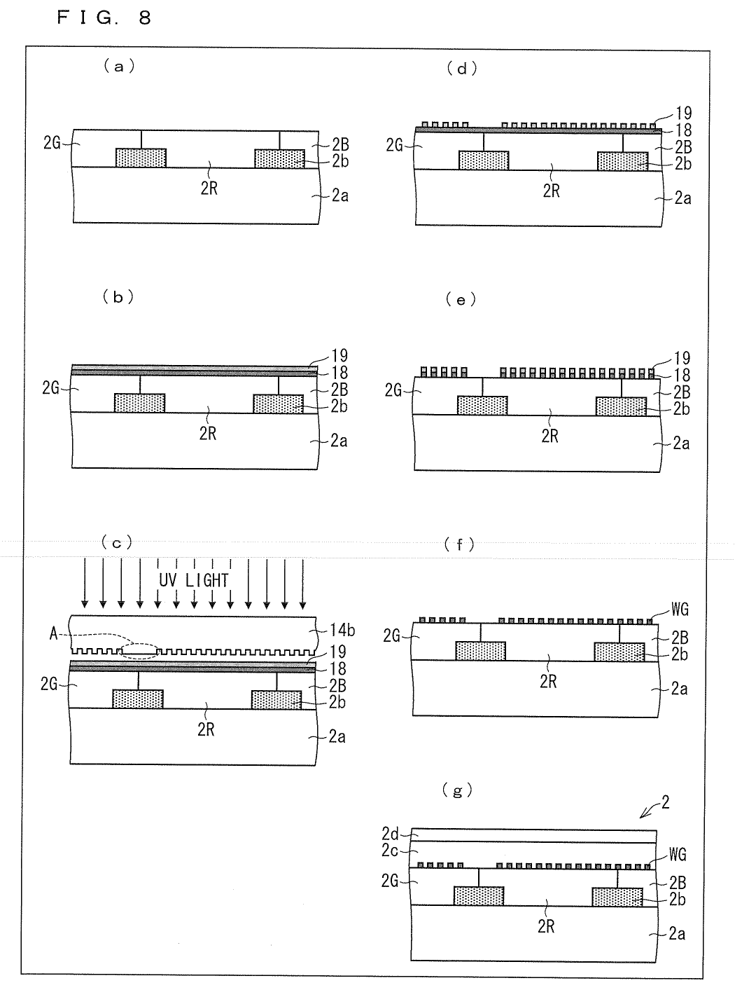

FIG. 8 is a view schematically illustrating a process of producing an in-cell wire grid polarizer WG included in the liquid crystal display device 1 shown in FIG. 2 with use of a large mold 14b.

As illustrated in (a) of FIG. 8, black matrices 2b having light blocking property are provided on a glass substrate 2a. The black matrices 2b are made from a thin metal film of for example chromium or from photosensitive resin containing carbon black. Further, a red colored layer 2R, a green colored layer 2G and a blue colored layer 2B are arranged such that a border between colors lies on a black matrix 2b.

Next, as illustrated in (b) of FIG. 8, a metal film 18 is formed on the red colored layer 2R, green colored layer 2G and blue colored layer 2B. On the metal film 18, a resist 19 is provided so that the resist 19 covers the metal film 18.

On these colored layers 2R, 2G and 2B, an overcoating made of thermosetting transparent resin or photo-curing transparent resin may be provided as a planarizing layer.

Next, in the step shown in (c) of FIG. 8, a large mold 14b is used. The patterned surface of the large mold 14b is different in shape from that of the large mold 14 produced in the step shown in FIG. 5.

The patterned surface of the large mold 14b is pressed against the resist 19 provided on the metal film 18 on the glass substrate 2a. Then, the resist 19 is exposed to UV light through the large mold 14b made of quartz. In this way, patterns of the resist 19, which patterns are complementary to the patterns formed in the patterned surface of the large mold 14b, are formed (i.e., a transferred surface corresponding to the patterned surface of the large mold 14b is formed) as illustrated in (d) of FIG. 8. That is, the patterns of the resist 19 are formed by a UV imprinting process.

It should be noted in the step shown in (c) of FIG. 8 that the large mold 14b is located such that a region A, of the patterned surface of the large mold 14b, in which patterns are at a pitch larger than a constant pitch overlaps a black matrix 2b when viewed from above.

Accordingly, as illustrated in (d) of FIG. 8, a region, of the resist 19, in which patterns are at a pitch larger than a constant pitch lies above a black matrix 2b.

After that, as illustrated in (e) of FIG. 8, etching is carried out by using as masks linear patterns of the resist 19, thereby linear patterns having a pitch smaller than a wavelength of light emitted from the surface light source device are formed in the metal film 18.

Then, as illustrated in (f) of FIG. 8, the linear patterns of the resist 19 used as the masks in the foregoing etching step are removed. In this way, it is possible to produce a wire grid polarizer WG on the red colored layer 2R, green colored layer 2G and blue colored layer 2B.

Lastly, as illustrated in (g) of FIG. 8, a protective film 2c is formed on the wire grid polarizer WG. On the protective film 2c, a transparent electrode 2d made of ITO (Indium Tin Oxide) or IZO (Indium Zinc Oxide) is formed. In this way, an in-cell wire grid polarizer WG included in the liquid crystal display device 1 is produced.

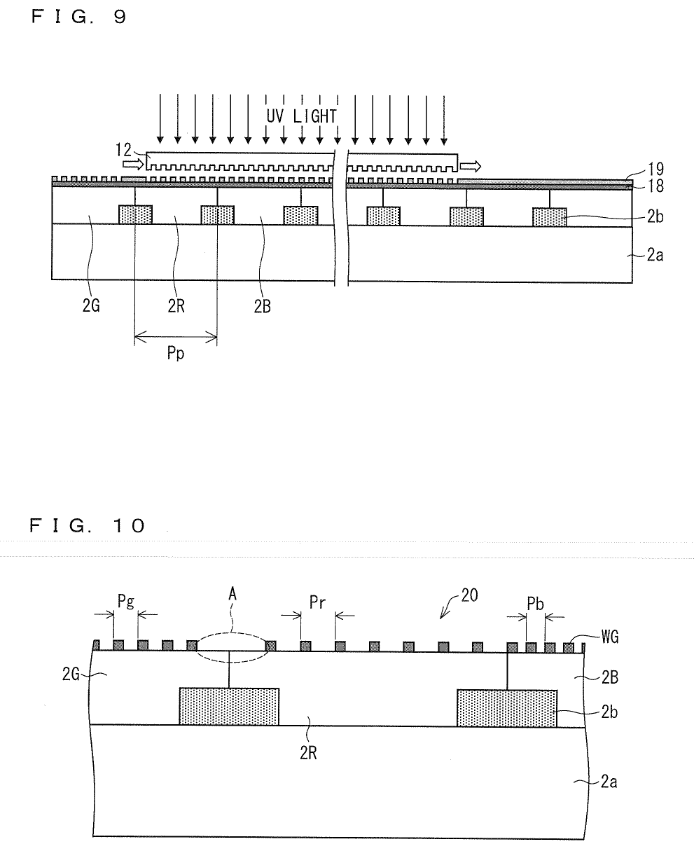

FIG. 9 is a view illustrating part of a process of producing an in-cell wire grid polarizer WG included in the liquid crystal display device 1 shown in FIG. 2 with use of the small mold 12.

As illustrated in FIG. 9, the patterned surface of the small mold 12 is pressed against a part of the resist 19 provided on the metal film 18 on the glass substrate 2a. Then, the part of the resist 19 is exposed to UV light through the small mold 12 made of quartz. In this way, patterns of the resist 19, which patterns are complementary to the patterns formed in the patterned surface of the small mold 12, are formed (i.e., a transferred surface corresponding to the patterned surface of the small mold 12 is formed) (transferring step). That is, the patterns of the resist 19 are formed by a UV imprinting process.

Further, the small mold 12 is relocated and this step is repeated. In this way, it is possible to form, on the entire surface of the resist 19 provided on the glass substrate 2a, patterns of the resist 19 which patterns are complementary to the patterns formed in the patterned surface of the small mold 12 (i.e., a transferred surface corresponding to the patterned surface of the small mold 12 is formed). That is, it is possible to form patterns in the entire surface of the resist 19 provided on the glass substrate 2a, by a step-and-repeat method.

Note here that, in this step, the patterns are formed in the entire surface of the resist 19 by a step-and-repeat method by relocating the small mold 12 such that a border region (joint) between (i) a region (first transferred surface) whose size is equivalent to that of the patterned surface of the small mold 12 and which is formed by a single transferring step and (ii) a region (second transferred surface) which is adjacent to the first transferred surface and is formed by the next transferring step overlaps a black matrix 2b when viewed from above.

It should be noted that, since the small mold 12 is preferably approximately several millimeters to several centimeters on a side, the small mold 12 according to the present embodiment is 5 mm on a side. However, the size of the small mold 12 is not limited to this.

Further, according to the present embodiment, the red colored layer 2R, the green colored layer 2G, the blue colored layer 2B and the back matrix 2b are arranged to have a pixel pitch Pp of 50 μm. A single transferring step with use of the small mold 12 can form patterns in a region of the resist 19 which region corresponds to 100 pixels.

According to the present embodiment, the optical sheet including the diffusing plate 9 as a diffusing member is provided on the light emitting surface of the surface light source device, which includes the light source 7 and the light guide plate 8 for emitting light from the light source 7 in the form of plane emission. That is, the optical sheet which includes the diffusing plate 9 and has a plurality of optical functions selected from diffusion, refraction, light collection and light polarization is provided. Note, however, that the light emitting surface of the surface light source device is not particularly limited provided that the light emitting surface (i) is an irregularly-shaped surface for diffusing light and/or (ii) has a diffusing member thereon for diffusing light.

Further, the foregoing irregular shape can be made by for example, but not particularly limited to, prism finishing, embossing, printing or the like. The foregoing irregular shape can be made by a well-known method as appropriate.

### Embodiment 2

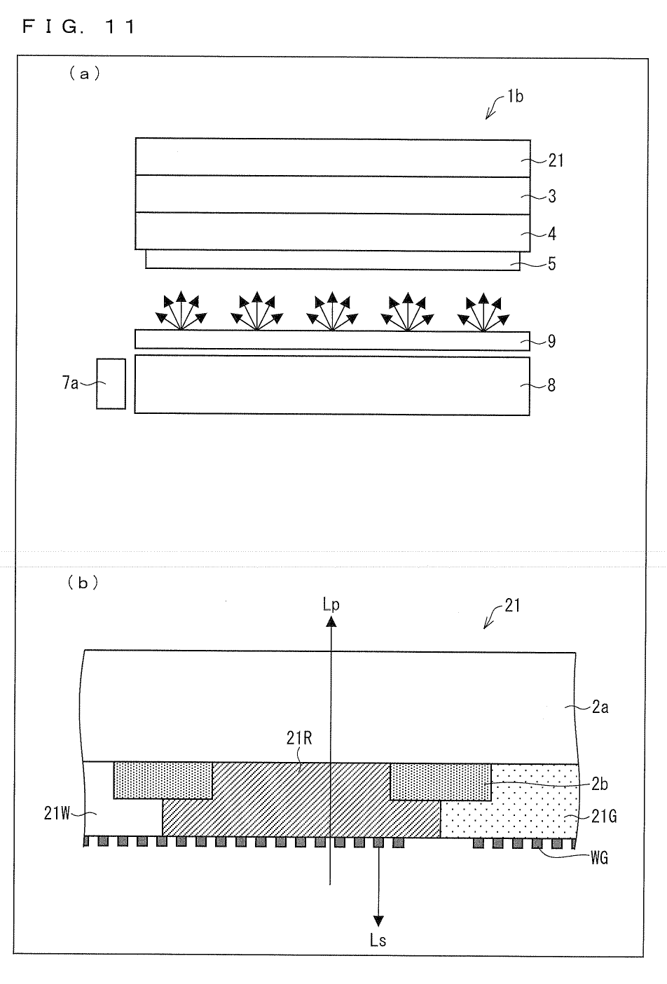

The following description discusses, with reference to FIG. 10, a second embodiment of the present invention. The present invention is different from Embodiment 1 in that a pitch Pr of the wire grid polarizer WG on the red colored layer 2R is configured to be relatively large, a pitch Pb of the wire grid polarizer WG on the blue colored layer 2B is configured to be relatively small, and a pitch Pg of the wire grid polarizer WG on the green colored layer 2G is configured to be between the pitch Pr and the pitch Pb. Other configurations are the same as those described in Embodiment 1. For convenience of description, members having functions identical to those illustrated in the drawings of Embodiment 1 are assigned identical referential numerals, and their descriptions are omitted here.

FIG. 10 illustrates a counter substrate 20 which is included in a liquid crystal display device of another embodiment of the present invention and which has an in-cell wire grid polarizer WG.

In a case where different kinds of light having different dominant wavelengths enter a region of the wire grid polarizer WG in which region linear conductive wires are regularly repeated at a constant pitch smaller than a wavelength of light for use in a display, variation occurs in a polarization extinction ratio. The polarization extinction ratio is a ratio of the amount of incident light to the amount of transmitted light when a polarization component parallel to the linear conductive wires enters the wire grid polarizer WG. This results in a reduction in display quality of a liquid crystal display panel.

For this reason, as illustrated in FIG. 10, the pitches Pr, Pg and Pb of the wire grid polarizer WG are configured to vary in such a way as to correspond to red light, green light, and blue light, respectively so that the polarization extinction ratio is substantially identical. The red light, green light, and blue light are from the red colored layer 2R, the green colored layer 2G, and the blue colored layer 2B, respectively and enter the wire grid polarizer WG.

That is, the pitch Pr of the wire grid polarizer WG on the red colored layer 2R is configured to be relatively large, the pitch Pb of the wire grid polarizer WG on the blue colored layer 2B is configured to be relatively small, and the pitch Pg of the wire grid polarizer WG on the green colored layer 2G is configured to be between the pitch Pr and the pitch Pb.

According to the above configuration, it is possible to suppress the foregoing reduction in display quality of the liquid crystal display panel.

### Embodiment 3

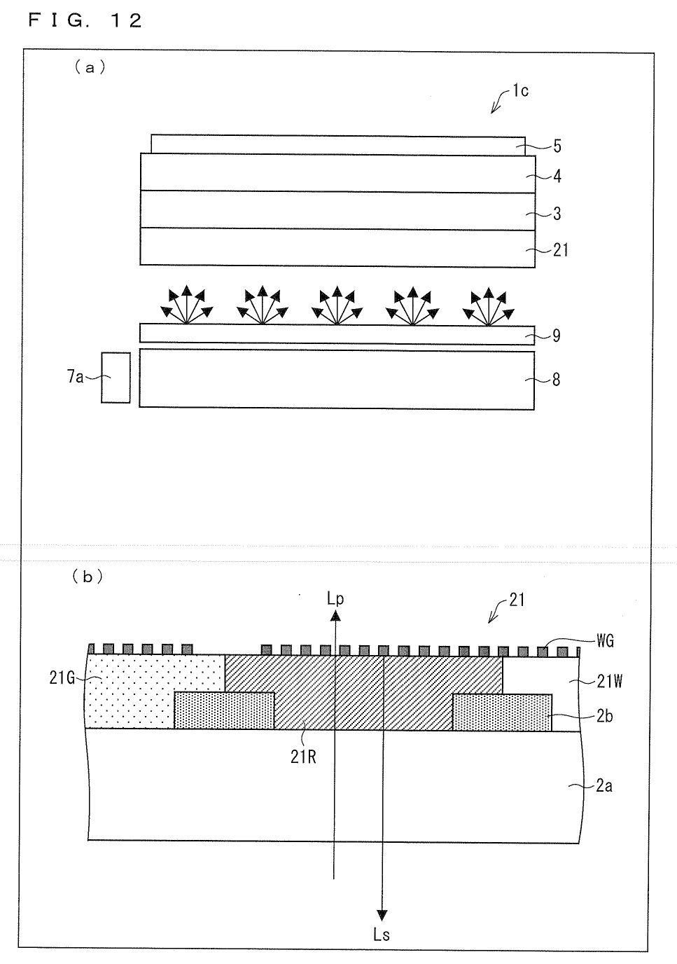

The following description discusses, with reference to FIGS. 11 to 14, the third embodiment of the present invention. The present embodiment is different from Embodiments 1 and 2 in that a color control layer is formed with use of a fluorescent material which converts incident light into light having other wavelength and then emits converted light. The other configurations are the same as those described in Embodiment 1. For convenience of description, members having functions identical to those illustrated in the drawings of Embodiment 1 are assigned identical referential numerals, and their descriptions are omitted here.

(a) of FIG. 11 illustrates a liquid crystal display device 1b employing as a light source 7a an LED (light emitting diode) which emits blue light. (b) of FIG. 11 illustrates a counter substrate 21 which is included in the liquid crystal display device 1b and has an in-cell wire grid polarizer WG.

As illustrated in (a) of FIG. 11, the liquid crystal display device 1b is configured such that a surface, of the counter substrate 21, which is opposite to a surface on which the in-cell wire grid polarizer WG is provided serves as a display surface of the liquid crystal display device 1b.

Further, as illustrated in (b) of FIG. 11, a green phosphor layer 21G for converting blue light from the light source 7a into green light, a red phosphor layer 21R for converting blue light from the light source 7a into red light, and a transparent resin layer 21W for directly transmitting blue light from the light source 7a, which layers serve as a color control layer, are provided so that a border between adjacent ones of the layers 21G, 21R and 21W lies on a black matrix 2b.

It should be noted that, as illustrated in (b) of FIG. 11, the pitch of the wire grid polarizer WG is configured to be the same for all the layers 21G, 21R and 21W because the wire grid polarizer WG receives only blue light from the light source 7a.

On the other hand, (a) of FIG. 12 illustrates a liquid crystal display device 1c employing as the light source 7a an LED which emits blue light, and (b) of FIG. 12 illustrates a counter substrate 21 which is included in the liquid crystal display device 1c and which has an in-cell wire grid polarizer WG.

As illustrated in (a) of FIG. 12, the liquid crystal display device 1c is configured such that a surface, of the counter substrate 21, which is opposite to a surface on which the in-cell wire grid polarizer WG is provided serves as a surface to be irradiated by the surface light source device including the light source 7a and the light guide plate 8.

Further, as illustrated in (b) of FIG. 12, a green phosphor layer 21G for converting blue light from the light source 7a into green light, a red phosphor layer 21R for converting blue light from the light source 7a into red light, and a transparent resin layer 21W for directly transmitting blue light from the light source 7a, which layers serve as a color control layer, are provided so that a border between adjacent ones of the layers 21G, 21R and 21W lies on a black matrix 2b.

According to (b) of FIG. 12, the pitch of the wire grid polarizer WG is the same for all the layers 21G, 21R and 21W. Note however that, as already described in Embodiment 2, it is preferable that the pitch of the wire grid polarizer WG be configured to vary in such a way as to correspond to red light, green light and blue light which enter the wire grid polarizer WG.

That is, it is preferable that the pitch of the wire grid polarizer WG on the red phosphor layer 21R be configured to be relatively large, the pitch of the wire grid polarizer WG on the transparent resin layer 21W be configured to be relatively small, and the pitch of the wire grid polarizer WG on the green phosphor layer 21G be configured to be between these two pitches.

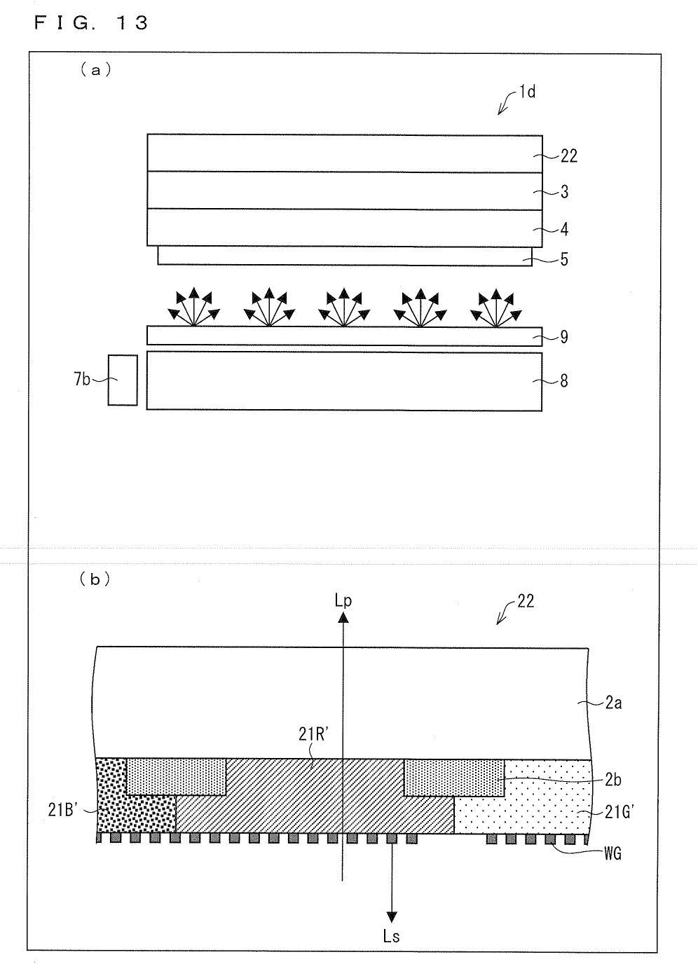

(a) of FIG. 13 illustrates a liquid crystal display device 1d employing as a light source 7b an LED which emits ultraviolet light. (b) of FIG. 13 illustrates a counter substrate 22 which is included in the liquid crystal display device 1d and which has an in-cell wire grid polarizer WG.

As illustrated in (a) of FIG. 13, the liquid crystal display device 1d is configured such that a surface, of the counter substrate 22, which is opposite to a surface on which the in-cell wire grid polarizer WG is provided serves as a display surface of the liquid crystal display device 1d.

Further, as illustrated in (b) of FIG. 13, a green phosphor layer 21G′ for converting ultraviolet light from the light source 7b into green light, a red phosphor layer 21R′ for converting ultraviolet light from the light source 7b into red light, and a blue phosphor layer 21B′ for converting ultraviolet light from the light source 7b into blue light, which layers serve as a color control layer, are provided so that a border between adjacent ones of the layers 21G′, 21R′ and 21B′ lies on a black matrix 2b.

As illustrated in (b) of FIG. 13, the pitch of the wire grid polarizer WG is configured to be the same for all the layers 21G′, 21R′ and 21B′ because the wire grid polarizer WG receives only ultraviolet light from the light source 7b.

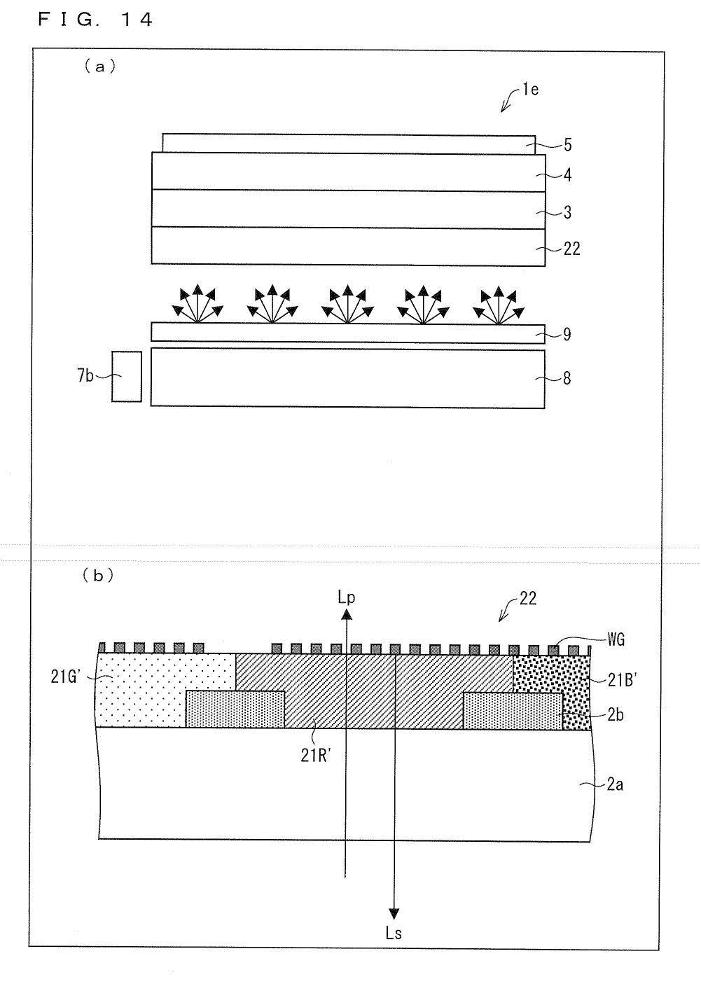

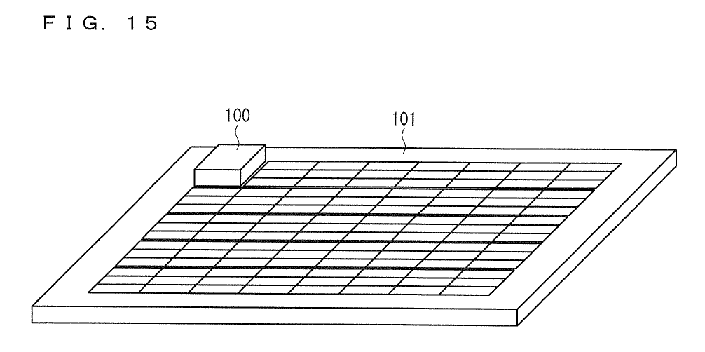

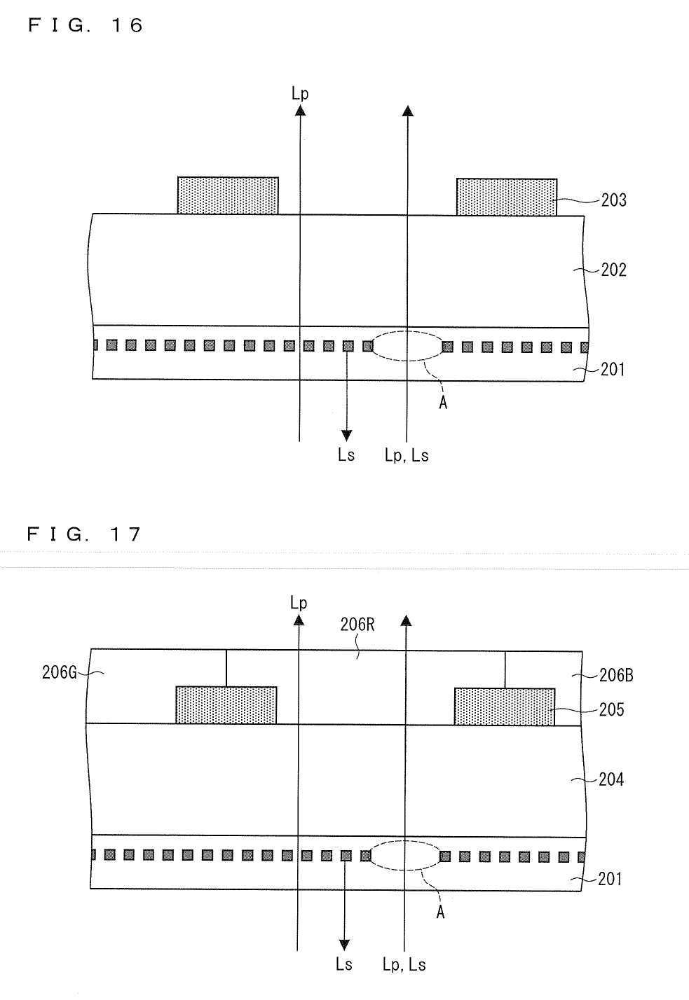

On the other hand, (a) of FIG. 14 illustrates a liquid crystal display device 1e employing as the light source 7b an LED which emits ultraviolet light, and (b) of FIG. 14 illustrates a counter substrate 22 which is included in the liquid crystal display device 1e and which has an in-cell wire grid polarizer WG.

As illustrated in (a) of FIG. 14, the liquid crystal display device 1e is configured such that a surface, of the counter substrate 22, which is opposite to a surface on which the in-cell wire grid polarizer WG is provided serves as a surface to be irradiated by the surface light source device including the light source 7a and the light guide plate 8.

Further, as illustrated in (b) of FIG. 14, a green phosphor layer 21G′ for converting ultraviolet light from the light source 7b into green light, a red phosphor layer 21R′ for converting ultraviolet light from the light source 7b into red light, and a blue phosphor layer 21B′ for converting ultraviolet light from the light source 7b into blue light, which layers serve as a color control layer, are provided so that a border between adjacent ones of the layers 21G′, 21R′ and 21B′ lies on a black matrix 2b.

According to (b) of FIG. 14, the pitch of the wire grid polarizer WG is the same for all the layers 21G′, 21R′ and 21B′. Note however that, as already described in Embodiment 2, it is preferable that the pitch of the wire grid polarizer WG be configured to vary in such a way as to correspond to red light, green light and blue light which enter the wire grid polarizer WG.

That is, it is preferable that the pitch of the wire grid polarizer WG on the red phosphor layer 21R′ be configured to be relatively large, the pitch of the wire grid polarizer WG on the blue phosphor layer 21B′ be configured to be relatively small, and the pitch of the wire grid polarizer WG on the green phosphor layer 21G′ be configured to be between these two pitches.

The liquid crystal display panel in accordance with the present invention is preferably configured such that the light shielding layer is a black matrix.

According to the configuration, the light shielding layer is the black matrix. This makes it unnecessary to separately provide, to the liquid crystal display panel, a light shielding film for blocking light which is to transmit the region where the linear conductive wires are at a pitch larger than the constant pitch and thus causes a reduction in display quality.

The liquid crystal display panel in accordance with the present invention is preferably configured such that the light shielding layer is a metal wire.

According to the configuration, the light shielding layer is for example the metal wire which is connected to an active element included in the liquid crystal display panel. This makes it unnecessary to separately provide, to the liquid crystal display panel, a light shielding film for blocking light which is to transmit the region where the linear conductive wires are at a pitch larger than the constant pitch and thus causes a reduction in display quality.

It is preferable that a liquid crystal display panel in accordance with the present invention further include two substrates between which a liquid crystal layer is held, and that the liquid crystal display panel be configured such that the wire grid polarizer is provided between the two substrates.

According to the configuration, the wire grid polarizer is provided between the two substrates (that is, provided in an in cell manner). This makes it possible to reduce thickness of the liquid crystal display panel while improving durability of the wire grid polarizer.

It is preferable that a liquid crystal display panel in accordance with the present invention further include a color control layer for emitting incident light as light of a plurality of colors, and that the liquid crystal display panel be configured such that: the wire grid polarizer is provided on the color control layer; and the constant pitch of the wire grid polarizer is configured to vary depending on a color of light that enters the wire grid polarizer through the color control layer so that a polarization extinction ratio is substantially identical, the polarization extinction ratio being a ratio of an amount of incident light to an amount of transmitted light when a polarization component parallel to the linear conductive wires enters the wire grid polarizer.

In a case where different kinds of light having different dominant wavelengths enter through the color control layer a region of the wire grid polarizer in which region the linear conductive wires are regularly repeated at the constant pitch smaller than the wavelength of light for use in a display, variation occurs in a polarization extinction ratio. This causes a reduction in display quality of the liquid crystal display panel.

According to the configuration, the constant pitch of the wire gird polarizer is configured to vary depending on a color of light that enters the wire grid polarizer through the color control layer so that the polarization extinction ratio is substantially identical.

Accordingly, it is possible to suppress the foregoing reduction in display quality of the liquid crystal display panel.

It should be noted that the color control layer is for example a layer that selectively transmits a certain wavelength(s) of incident light entering the color control layer or converts incident light into light having other wavelength and then emits converted light. Note, however, that the color control layer is not limited to the above provided that it is capable of emitting incident light as light having a plurality of colors.

The liquid crystal display panel in accordance with the present invention is preferably configured such that: the color control layer includes a first color control layer for emitting incident light as red light, a second color control layer for emitting incident light as green light, and a third color control layer for emitting incident light as blue light; the constant pitch of the wire grid polarizer on the first color control layer is configured to be a relatively large pitch; the constant pitch of the wire grid polarizer on the third color control layer is configured to be a relatively small pitch; and the constant pitch of the wire grid polarizer on the second color control layer is configured to be between the relatively large pitch and the relatively small pitch.

It is known that, in a case where red light, green light and blue light which have respective different dominant wavelengths enter through the color control layers the region of the wire grid polarizer in which region the linear conductive wires are regularly repeated at the constant pitch smaller than the wavelength of light for use in a display, the red light having the largest dominant wavelength has the largest polarization extinction ratio and the blue light having the smallest dominant wavelength has the smallest polarization extinction ratio.

In a case where variation occurs in the polarization extinction ratio like above, a reduction is caused in display quality of the liquid crystal display panel.

According to the above configuration, the constant pitch of the wire grid polarizer on the color control layer which emits the incident light as red light is configured to be relatively large, the constant pitch of the wire grid polarizer on the color control layer which emits the incident light as blue light is configured to be relatively small, and the constant pitch of the wire grid polarizer on the color control layer which emits the incident light as green light is configured to be between (i) the constant pitch of the wire grid polarizer on the color control layer which emits the incident light as red light and (ii) the constant pitch of the wire grid polarizer on the color control layer which emits the incident light as blue light. This makes it possible to suppress variation in the polarization extinction ratio.

The liquid crystal display panel in accordance with the present invention is preferably configured such that the color control layer is a colored layer or a phosphor layer.

According to the configuration, it is possible to form the color control layer from the colored layer which selectively transmits a certain wavelength(s) of incident light or from the phosphor layer which converts incident light into light having other wavelength and then emits converted light.

The method for producing a liquid crystal display panel in accordance with the present invention is preferably configured such that: the resist is a thermosetting resist; and the thermosetting resist is cured by heat treatment.

The method for producing a liquid crystal display panel in accordance with the present invention is preferably configured such that: the resist is a photo-curing resist; the first mold is made of a light-transmitting material; and the photo-curing resist is cured by exposure to light.

The method for producing a liquid crystal display panel in accordance with the present invention is preferably configured such that: the resist is a photo-curing resist; the second mold is made of a light-transmitting material; and the photo-curing resist is cured by exposure to light.

The present invention is not limited to the descriptions of the respective embodiments, but may be altered within the scope of the claims. An embodiment derived from a proper combination of technical means disclosed in different embodiments is encompassed in the technical scope of the invention.

### INDUSTRIAL APPLICABILITY

The present invention is applicable to a liquid crystal display panel, a liquid crystal display device and the like.

### REFERENCE SIGNS LIST

1, 1a, 1b, 1c, 1d, 1e Liquid crystal display device
2, 20, 21, 22 Counter substrate (substrate)
2b Black matrix (Light shielding layer)
2R, 2G, 2B Colored layer (color control layer)
3 Liquid crystal layer
9 Diffusing plate (diffusing member)
12 Small mold (first mold)
14, 14a, 14b, 16 Large mold (second mold)
18 Metal film (conductive film)
19 Resist
21R, 21G Phosphor layer (color control layer)
21R″ 21G′ 21B′ Phosphor layer (color control layer)
21W Transparent resin layer (color control layer)
WG Wire grid polarizer
A Region where regularity is disturbed
Lp Polarization component perpendicular to conductive wire
Ls Polarization component parallel to conductive wire
P Pitch

1. A liquid crystal display panel comprising:
a wire grid polarizer which has a pattern of linear conductive wires having a pitch smaller than a wavelength of light for use in a display; and
a light shielding layer,
the wire grid polarizer having (i) a first region where the linear conductive wires are regularly repeated at a constant pitch and (ii) a second region where the linear conductive wires are at a pitch larger than the constant pitch, and
the second region and the light shielding layer being arranged so as to at least partially overlap each other when viewed from above.

2. The liquid crystal display panel according to claim 1, wherein the light shielding layer is a black matrix.

3. The liquid crystal display panel according to claim 1, wherein the light shielding layer is a metal wire.

4. The liquid crystal display panel according to claim 1, further comprising two substrates between which a liquid crystal layer is held,
the wire grid polarizer being provided between the two substrates.

5. The liquid crystal display panel according to claim 1, further comprising a color control layer for emitting incident light as light of a plurality of colors, wherein:
the wire grid polarizer is provided on the color control layer; and
the constant pitch of the wire grid polarizer is configured to vary depending on a color of light that enters the wire grid polarizer through the color control layer so that a polarization extinction ratio is substantially identical, the polarization extinction ratio being a ratio of an amount of incident light to an amount of transmitted light when a polarization component parallel to the linear conductive wires enters the wire grid polarizer.

6. The liquid crystal display panel according to claim 5, wherein:
the color control layer includes a first color control layer for emitting incident light as red light, a second color control layer for emitting incident light as green light, and a third color control layer for emitting incident light as blue light;
the constant pitch of the wire grid polarizer on the first color control layer is configured to be a relatively large pitch;
the constant pitch of the wire grid polarizer on the third color control layer is configured to be a relatively small pitch; and
the constant pitch of the wire grid polarizer on the second color control layer is configured to be between the relatively large pitch and the relatively small pitch.

7. The liquid crystal display panel according to claim 5, wherein the color control layer is a colored layer or a phosphor layer.

8. A liquid crystal display device comprising:
a liquid crystal display panel recited in claim 1; and
a surface light source device for irradiating the liquid crystal display panel with light,
the surface light source device (i) having an irregularly-shaped light emitting surface for scattering light and/or (ii) having on its light emitting surface a diffusing member for scattering light.

9. A method for producing a liquid crystal display panel, the liquid crystal display panel including (i) a wire grid polarizer which has a pattern of linear conductive wires having a pitch smaller than a wavelength of light for use in a display and (ii) substrates, said method comprising the steps of:
(A) forming, on one of the substrates, a light shielding layer patterned into a predetermined shape;
(B) forming, evenly on an entire surface of said one of the substrates, a conductive film which is to be formed into the conductive wires;
(C) forming a resist so that the resist covers the conductive film;
(D) curing a part of the resist while pressing a patterned surface of a first mold against the part of the resist, the patterned surface being a surface in which linear patterns regularly repeated at a constant pitch smaller than the wavelength of the light are formed, to thereby form in the resist a first transferred surface on which the linear patterns in the patterned surface have been transferred;
(E) after relocating the first mold to a position adjacent to the first transferred surface, curing another part of the resist while pressing the patterned surface of the first mold against said another part of the resist to thereby form in the resist a second transferred surface on which the linear patterns in the patterned surface have been transferred;
in steps (D) and (E), locating the first mold such that a border between the first transferred surface and the second transferred surface at least partially overlaps the light shielding layer when viewed from above;
(F) etching the conductive film by using cured resist patterns as masks; and
(G) removing the cured resist patterns.

10. A method for producing a liquid crystal display panel, the liquid crystal display panel including (i) a wire grid polarizer which has a pattern of linear conductive wires having a pitch smaller than a wavelength of light for use in a display and (ii) substrates, said method comprising the steps of:
(A) forming, on one of the substrates, a light shielding layer patterned into a predetermined shape;
(B) forming, evenly on an entire surface of said one of the substrates, a conductive film which is to be formed into the conductive wires;
(C) forming a resist so that the resist covers the conductive film;
(D) curing the resist while pressing a patterned surface of a second mold against the resist, the patterned surface of the second mold having (i) a first region in which linear patterns regularly repeated at a constant pitch smaller than the wavelength of the light are formed and (ii) a second region in which linear patterns are at a pitch larger than the constant pitch;
in step (D), locating the second mold such that the second region at least partially overlaps the light shielding layer when viewed from above;
(E) etching the conductive film by using cured resist patterns as masks; and
(F) removing the cured resist patterns.

11. (canceled)

12. The method according to claim 9, wherein:
the resist is a photo-curing resist;
the first mold is made of a light-transmitting material; and
the photo-curing resist is cured by exposure to light.

13. The method according to claim 10, wherein:
the resist is a photo-curing resist;
the second mold is made of a light-transmitting material; and
the photo-curing resist is cured by exposure to light.

14. The method according to claim 9, wherein:
the resist is a thermosetting resist; and
the thermosetting resist is cured by heat treatment.

15. The method according to claim 10, wherein:
the resist is a thermosetting resist; and
the thermosetting resist is cured by heat treatment.
